(19) United States
(12) Patent Application Publication
(10) Pub. No.: US 2016/0093352 A1
(43) Pub. Date: Mar. 31, 2016

(54) REFERENCE VOLTAGE GENERATION FOR SENSING RESISTIVE MEMORY

(71) Applicant: QUALCOMM Incorporated, San Diego, CA (US)

(72) Inventors: Seong-Ook JUNG, Seoul (KR); Taehui NA, Seoul (KR); Jisu KIM, Seoul (KR); Jung Pill KIM, San Diego, CA (US); Seung Hyuk KANG, San Diego, CA (US)

(21) Appl. No.: 14/499,156

(22) Filed: Sep. 27, 2014

(51) Int. Cl. G11C 11/16

(52) U.S. Cl. CPC G11C 11/1673

(57) ABSTRACT

Systems and methods relate to providing a correct reference voltage for reading a resistive memory element such as a magnetoresistive random access memory (MRAM) bit cell. Two or more reference voltages are provided for each MRAM bit cell and a correct reference voltage is selected from the two or more reference voltages for reading the MRAM bit cell. The correct reference voltage meets sensing margin requirements for reading the MRAM bit cell and overcomes non-idealities and offset voltages in read circuitry for reading the MRAM bit cell. An indication of the correct reference voltage is stored in a non-volatile latch or other non-volatile programmable memory and provided to the read circuitry.

### FIELD OF DISCLOSURE

Disclosed aspects are directed to providing reference voltage for sensing resistive memory bit cells, where the reference voltage is corrected for process variations. More specifically, exemplary aspects relate to selecting one of two or more reference voltages to provide a corrected reference voltage to a sense amplifier used to sense magnetoresistive random access memory (MRAM) bit cells.

### BACKGROUND

Memory devices conventionally include arrays of bit cells that each store a bit of data.

Each data bit can represent a logical zero (“0”) or a logical one (“1”), which may correspond to a state of the bit cell. During a read operation of a selected bit cell, a voltage level close to ground may be representative of “0” and a relatively higher voltage level may be representative of “1”. Bit lines are coupled to various bit cells in the memory array and the bit lines couple the bit cells to other components used in read/write operations.

Magnetoresistive random access memory (MRAM) is a non-volatile memory technology where data is stored based on magnetization polarities of bit cells. In contrast to conventional RAM technologies which store data as electric charges or current flows, MRAM uses magnetic elements. A magnetic tunnel junction (MTJ) which is conventionally used as a storage element or bit cell for MRAM technology, can be formed from two magnetic layers, each of which can hold a magnetic moment, separated by an insulating (tunnel barrier) layer. Conventionally, the fixed layer is set to a particular polarity. The free layer's polarity is free to change to match that of an external magnetic field that can be applied. A change in the polarity of the free layer will change the resistance of the MTJ bit cell. For example, when the magnetization polarities are aligned or “parallel,” a low resistance state exists, which corresponds to a logical “0”. When the magnetization polarities are not aligned or are “anti-parallel,” a high resistance state exists, which corresponds to a logical “1”.

Thus, in magnetoresistive random access memory (MRAM), each bit cell (e.g., a MTJ bit cell) has a resistance value based on whether the bit cell represents a logical zero (“0”) or a logical one (“1”). Specifically, the resistance of the bit cell (R_{data}) relates to the data stored in the bit cell. In order to read the bit cell, a sensing current is passed through the bit cell and a voltage V_{data} developed across the resistance R_{data} is then compared to a reference voltage V_{ref}. The reference voltage V_{ref} is generated by passing the same current through a reference cell which has been programmed to a known resistance value. If V_{data} is high relative to V_{ref}, then then the bit cell is determined to have a logical “1” stored therein. If V_{data} is low relative to V_{ref}, then then the bit cell is determined to have a logical “0” stored therein. The difference between the voltage across the bit cell V_{data} and the reference voltage V_{ref}, (differential voltage ΔV=V_{data}−V_{ref}) is therefore used to indicate the logic state stored in the the bit cell.

A sensing circuit is conventionally used to sense the differential voltage ΔV, whether it is positive or negative. A sense amplifier, as is known in the art is then used to amplify the sensed differential voltage ΔV to provide a read output value of “1” if ΔV is positive and a read output value of “0” if ΔV is negative. A sensing margin refers generally refers to the amount by which ΔV must be correctly sensed as positive or negative in order to correctly read the value stored in the bit cell as “1” or “0” respectively. This sensing margin can degrade due to non-idealities which are introduced, for example, due to technology scaling, which can disrupt the read process.

Technology scaling and process variations can introduce variations in the sizes and electrical properties of the various transistors and circuit elements that are employed in constructing the bit cell, the sensing circuit, the sense amplifier, etc., which are used for reading the bit cell. Effects of such process variations in the read circuitry are generally referred to as offsets or offset voltages in this disclosure. Such offsets are discussed with relation to the sensing margin or difference between V_{ref} and V_{data}.

For example, the reference cell may deviate from its expected size and/or resistance characteristics in relation to the bit cell, based on process variations. This may lead to the generation of a reference voltage V_{ref} that deviates from its expected value. In turn, the sensing margin degrades. Such effects are more pronounced at shrinking technology nodes as even minor variations can result in relatively large fluctuations.

Further, the sensing current that is passed through R_{data} to generate V_{data} may be reduced to avoid an undesirable side effect of read disturbance phenomenon. Read disturbance refers to a situation where the passage of the sensing current for reading the bit cell may inadvertently disturb the value stored in the bit cell (e.g., by disturbing the alignment of the free layer with respect to the fixed layer of the MTJ described above). Thus, adjusting the sensing current to avoid read disturbance may lead to undesirable fluctuations in the value of V_{data}, once again causing potential degradation of the sensing margin.

Some conventional approaches try to combat the degradation of the sensing margin by utilizing offset-cancellation circuits to cancel out the effects of the offset voltages of the read circuitry (e.g., comprising a sensing circuit and a sense amplifier). However, these conventional offset-cancellation circuits include multiple stage sensing circuits which may themselves suffer from the negative effects of process variations. Moreover, they also increase power costs and introduce undesirable delays. As such, there is a need in the art to improve sensing margin while avoiding the aforementioned drawbacks.

### SUMMARY

Exemplary aspects are directed to providing correct reference voltage for sensing resistive memory bit cells, where the correct reference voltage overcomes process variations in read circuitry and other non-idealities in reading the resistive memory bit cells. For example, in some aspects, the correct reference voltage is selected from one of two or more reference voltages and provided to a read circuitry for reading magnetoresistive random access memory (MRAM) bit cells.

Accordingly, an exemplary aspect relates to a method of reading a magnetoresistive random access memory (MRAM) bit cell, the method comprising providing two or more reference voltages for the MRAM bit cell, selecting a correct reference voltage from the two or more reference voltages for reading the MRAM bit cell, based on sensing margin requirements for reading the MRAM bit cell, and reading the MRAM bit cell based on the correct reference voltage.

Another exemplary aspect relates to an apparatus comprising: a magnetoresistive random access memory (MRAM) bit cell, and read circuitry configured to perform a read operation on the MRAM bit cell. A multiplexor configured to select a correct reference voltage from two or more reference voltages, based on sensing margin requirements for the read circuitry.

Yet another exemplary aspect is directed to a system comprising: a magnetoresistive random access memory (MRAM) bit cell, means for providing two or more reference voltages for the MRAM bit cell, means for selecting a correct reference voltage from the two or more reference voltages for reading the MRAM bit cell, wherein the correct reference voltage meets sensing margin requirements for reading the MRAM bit cell, and means for reading the MRAM bit cell based on the correct reference voltage.

### BRIEF DESCRIPTION OF THE DRAWINGS

The accompanying drawings are presented to aid in the description of embodiments of the invention and are provided solely for illustration of the embodiments and not limitation.

FIG. 1 is a schematic illustration depicting the degradation of sensing margin for reading MRAM bit cells, according to conventional approaches.

FIG. 2 is a schematic illustration of an exemplary aspect for combating the degradation of sensing margin for reading exemplary MRAM bit cells.

FIG. 3 is a flow chart depiction of an exemplary process for selecting the correct reference voltage for reading a bit cell of an exemplary MRAM.

FIG. 4A is a schematic illustration of circuit 400 for implementing an exemplary read process for an MRAM.

FIG. 4B illustrates a schematic depiction of a reference voltage generator for generating reference voltages for an exemplary MRAM.

FIGS. 5A-D illustrate exemplary circuit schematics for a sensing circuit, a non-volatile latch, a sense amplifier, and a 2:1 MUX used for an exemplary read operation according to disclosed aspects.

FIG. 6 illustrates a flow chart for providing a correct reference voltage for reading a

MRAM bit cell, according to an exemplary aspect.

FIG. 7 illustrates a high-level diagram of a wireless device in which exemplary aspects may be advantageously employed.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The words “exemplary” and/or “example” are used herein to mean “serving as an example, instance, or illustration.” Any embodiment described herein as “exemplary” and/or “example” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

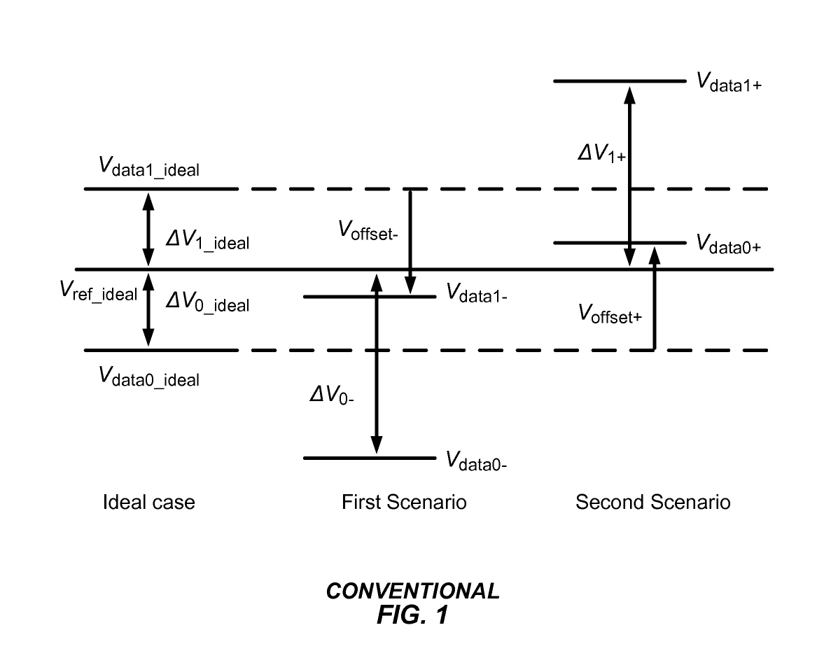

With reference to FIG. 1, a schematic illustration depicting the degradation of sensing margin for reading MRAM bit cells, according to conventional approaches, is provided. The voltages V_{data0}_{_{—}}_{ideal} and V_{data1}_{_{—}}_{ideal} are shown for an ideal case, which depict the V_{data} values corresponding to logical “0” and “1” stored in a bit cell, respectively, in relation to an ideal reference voltage V_{ref}_{_{—}}_{ideal}. In this depiction, voltage values increase upwards from V_{data0}_{_{—}}_{ideal}, which means that V_{data1}_{_{—}}_{ideal} is greater than or more positive than V_{data0}_{_{—}}_{ideal}. V_{data0}_{_{—}}_{ideal} and V_{data1}_{_{—}}_{ideal} would be the voltage values developed across R_{data} of the bit cell the value of V_{ref}_{_{—}}_{ideal} for sensing the V_{data} across R_{data} would optimally be at point midway between V_{data0}_{_{—}}_{ideal} and V_{data1}_{_{—}}_{ideal}. Thus, in the ideal case, ΔV₁_{_{—}}_{ideal}=V_{data1}_{_{—}}_{ideal}−V_{ref}_{_{—}}_{ideal} would be positive (i.e., if V_{data1}_{_{—}}_{ideal} is greater than V_{ref}_{_{—}}_{ideal}) with a sufficient sensing margin to be able to provide a correct read data value of “1.” Similarly, ΔV₀_{_{—}}_{ideal}=V_{data0}_{_{—}}_{ideal}−V_{ref}_{_{—}}_{ideal} would be negative (i.e., if V_{data0}_{_{—}}_{ideal} is less than V_{ref}_{_{—}}_{ideal}) with a sufficient sensing margin to be able to provide a correct read data value of “0.”

However, due to non-idealities and offsets that are developed in the reading circuit, in a first scenario, the voltage V_{data} may effectively shift to lower than expected values V_{data1-} and V_{data0-} for logical “1” and “0” stored in the bit cell, respectively, in relation to the ideal reference voltage. This first scenario includes a representative first offset V_{offset-}, which depicts the amount by which V_{data} may have effectively shifted due to the process variations in the read circuitry comprising a sensing circuit and a sense amplifier, for example, the effective shift being relative to V_{ref}_{_{—}}_{ideal}. In this case, if a value corresponding to logical “1” is stored in the bit cell, then ΔV₀₋=V_{data0-}−V_{ref}_{_{—}}_{ideal} is correctly seen to be a negative value as expected. However, while ΔV₁₋=V_{data1-}−V_{ref}_{_{—}}_{ideal} is expected to be a positive value in order for the bit cell to be correctly read as a logical “1,” it is seen that V_{data1-} is in fact less than or more negative than V_{ref}_{_{—}}_{ideal}, which means that ΔV₁₋ would be sensed to be a negative value, thus resulting in an incorrect read output.

Similarly, in the depicted second scenario, the voltage V_{data} may effectively shift to higher than expected values V_{data1+} and V_{data0+} for logical “1” and “0” stored in the bit cell, respectively, the shift, once again, being relative to V_{ref}_{_{—}}_{ideal}. This second scenario is shown to have a representative second offset V_{offset+}. Thus, if a value corresponding to logical “0” is stored in the bit cell, then ΔV₁₊=V_{data1+}−V_{ref}_{_{—}}_{ideal} would be a positive value as expected. However, while ΔV₀₊=V_{data0+}−V_{ref}_{_{—}}_{ideal} is expected to be negative in order for the bit cell to be correctly read as a logical “0,” it is seen that V_{data0+} is in fact larger or more positive than V_{ref}_{_{—}}_{ideal}, which means that ΔV₀₊ would be sensed to be a positive value, thus resulting in an incorrect read output.

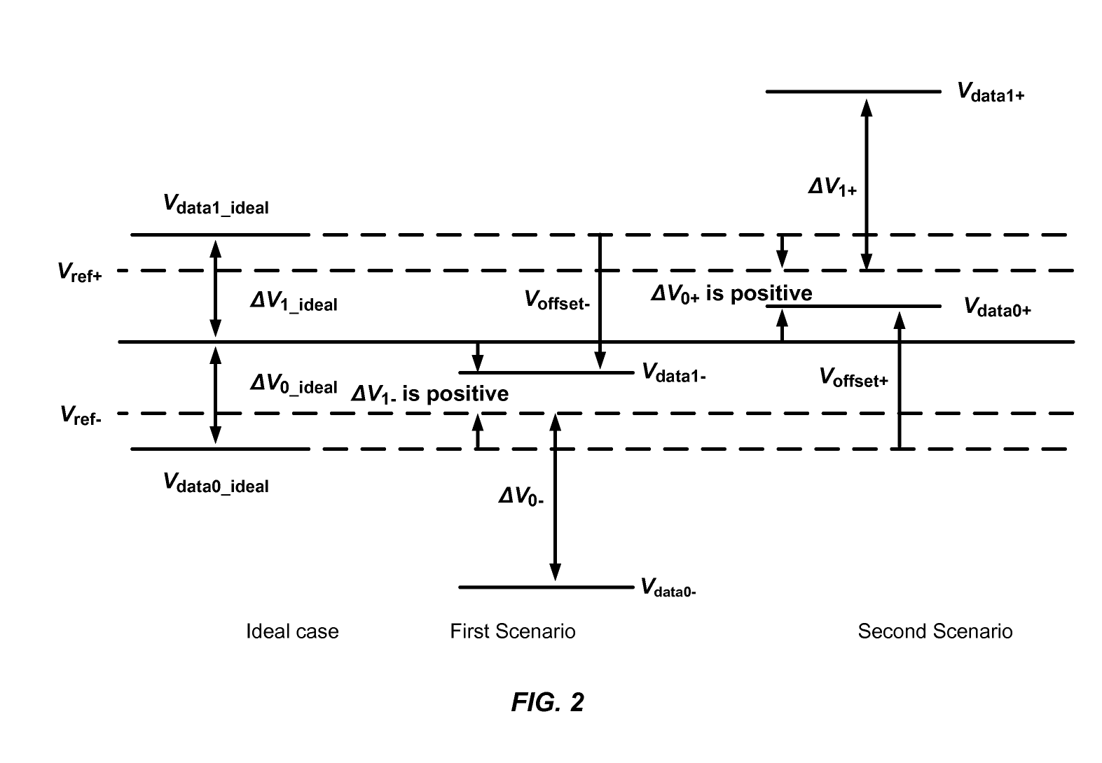

With reference now to FIG. 2, a schematic illustration of an exemplary aspect is provided, wherein the incorrect read outputs in the first and second scenarios of FIG. 1 are rectified. In more detail, rather than rely on a single or universal reference voltage (e.g., V_{ref}_{_{—}}_{ideal}), two or more reference voltages are provided to combat the negative effects of offset voltages in the read circuitry for an MRAM bit cell and corresponding degradation of sensing margin. Thus, as shown once again, in the ideal case, ΔV₁_{_{—}}_{ideal}=V_{data1}_{_{—}}_{ideal}−V_{ref}_{_{—}}_{ideal} would be positive with a sufficient sensing margin to be able to provide a correct read data value of “1,” and ΔV₀_{_{—}}_{ideal}=V_{data0}_{_{—}}_{ideal}−V_{ref}_{_{—}}_{ideal} would be negative with a sufficient sensing margin to be able to provide a correct read data value of “0.” In order to ensure that ΔV₁ is positive and ΔV₀ is negative for both the first and second scenarios as well, two additional reference voltages V_{ref+} and V_{ref-} are provided in FIG. 2.

With reference to the first scenario shown in FIG. 2, in order to combat the undesirable effects of V_{offset-}, a first reference voltage V_{ref-} is provided, which is less than or more negative than V_{ref}_{_{—}}_{ideal}. Thus, when reading an exemplary bit cell with resistance R_{data}, current is passed through the bit cell and voltage V_{data} is developed across the bit cells as previously described. However, in exemplary aspects, rather than compare V_{data} with V_{ref}_{_{—}}_{ideal}, in the first scenario, V_{data} is compared with V_{ref-}. More specifically, the voltage differences are calculated as follows: ΔV₁₋=V_{data1-}−V_{ref-} and ΔV₀₋=V_{data0-}−V_{ref-}. With an appropriately chosen value of V_{ref-}, for example, as illustrated in FIG. 2, ΔV₁₋ is a positive value, as expected, and ΔV₀₋ is a negative value, as expected. Accordingly, the problem of incorrect read outputs in the first scenario can be solved by providing an appropriate value of the first reference voltage V_{ref-}. Aspects related to determining and providing V_{ref-} for an appropriate bit cell will be elaborated in the following sections.

Similarly, for the second scenario shown in FIG. 2, if the offset is V_{offset+}, a second reference voltage, V_{ref+} is provided, which is larger or more positive than V_{ref}_{_{—}}_{ideal}, as shown. In this case, the voltage differences are calculated as follows: ΔV₁₊=V_{data1+}−V_{ref+} and ΔV₀₊=V_{data0+}−V_{ref+}. With an appropriately chosen value of V_{ref+}, for example, as illustrated in FIG. 2, ΔV₁₊ is a positive value, as expected, and ΔV₀₊ is a negative value, as expected. Accordingly, the problem of incorrect read outputs in the second scenario can be solved by providing an appropriate value of the second reference voltage, V_{ref+}. Once again, aspects related to determining and providing V_{ref+} for an appropriate bit cell will be elaborated in the following sections.

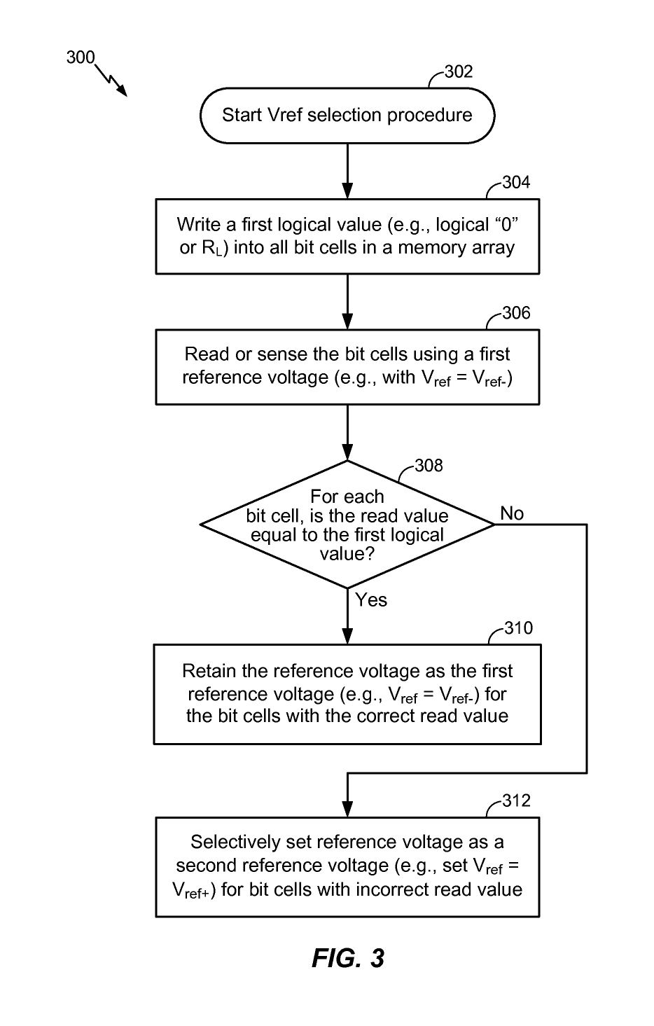

With reference now to FIG. 3, a flow chart pertaining to an exemplary process for selecting the correct reference voltage for each bit cell of a memory array is depicted. For example, a MRAM array comprising a selected number of MRAM bit cells is considered. In some aspects, the selected number of bit cells referred to in FIG. 3 may be a subset or a sub-array of the memory array with a predetermined number of rows and columns of bit cells, rather than the entire memory array. For each bit cell, process 300 of FIG. 3 assumes that one of the two reference voltages, the first reference voltage V_{ref-} or the second reference voltage V_{ref+,} would be the correct reference voltage value that will enable the data value stored in the bit cell to be read correctly. While this assumption is described at length in exemplary aspects, it will be understood that the described examples can be easily extended to cases where a correct reference voltage may be selected from more than two reference voltages. Accordingly, based on particular needs, the reference voltage for any selected number of bit cells of a memory array can be selected from any number of one or more reference voltages which will enable a correct read operation on the selected number of bit cells.

Thus, FIG. 3 shows process 300 which starts a V_{ref} selection procedure in Block 302 for selecting the appropriate reference voltage for a selected number of one or more bit cells (e.g., MRAM or MTJ bit cells) of a memory array (e.g., MRAM array). At Block 304, a first logical value is written to all of the selected bit cells. This first logical value may be, for example, a logical “0” which corresponds to a low value of R_{data}, depicted as R_{L} herein. At block 306, the selected bit cells are all read or sensed using a first of one or more reference voltages (e.g., first reference voltage V_{ref-}). It will be recalled from the discussion of the first and second scenarios in FIGS. 1 and 2, that the logical value of “0” corresponds to the problematic case which may result in an incorrect read when the reference voltage is V_{ref} (which is less than V_{ref}_{_{—}}_{ideal} and therefore, testing the read value using V_{ref-} will ensure that a correct read value indicates that the bit cell has an offset V_{offset-}, as depicted in the first scenario, for example. If, on the other hand, at Block 304, the bit cells were written with a logical “1” which corresponds to a high value of R_{data} (or R_{H}), then in Block 306, the selected bit cells would be sensed using V_{ref+}, corresponding to second scenario, for example. The below processes will be described with the example of the first logical value being equal to “0,” and the first reference voltage being V_{ref}, without loss of generality.

In decision Block 308, for each bit cell, it is determined whether the read values is correct, or in other words, matches the first logical value that was written. In Block 310, the reference voltage for the bit cells whose read values are correct is assigned or retained at the first reference voltage. Thus, the first reference voltage is treated as the correct reference voltage for these bit cells whose read values are correct. On the other hand, in Block 312, the reference voltages for the bit cells whose read values are incorrect are selectively assigned to a second reference voltage (e.g., second reference voltage V_{ref+}). Thus, the second reference voltage is treated as the correct reference voltage for the bit cells whose read values are incorrect.

Setting and storing the reference voltages as the selected one of the first or second reference voltage in Blocks 310 and 312, respectively, may be accomplished by storing the selected reference voltage in a memory element, such as, a non-volatile (NV) latch, which will be further explained below. It will also be understood that even though the example of the NV latch will be discussed at length, the selected reference voltage for a first MRAM bit cell, for example, can be also stored in a second MRAM bit cells (e.g., additional memory cells provided in the MRAM array). Information pertaining to the selected reference voltage can be transferred to corresponding volatile latches during or after power-up of the memory array, for example, in such cases. The selected reference voltage information can also be stored in a one-time programmable (OTP) memory or electrically erasable programmable read only memory (EEPROM), which may be located outside the memory array. The selected reference voltage or indication thereof can be stored in the OTP memory or the EEPROM prior to power up of the memory array or MRAM, and can be serially transferred to corresponding volatile latches during or after power-up of the memory array.

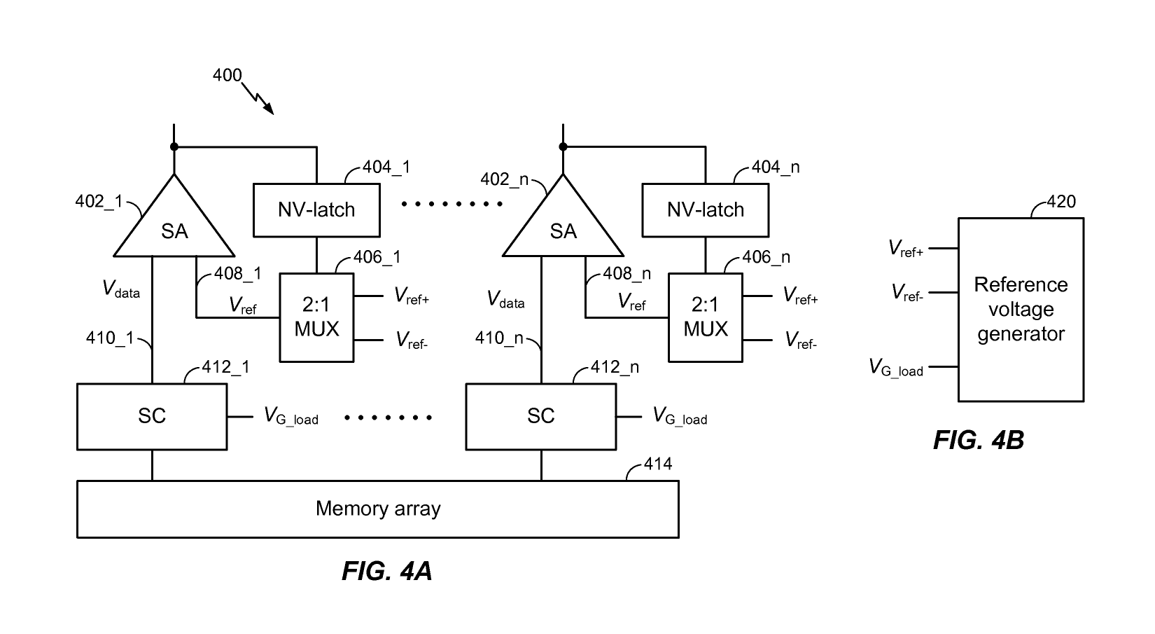

With reference now to FIG. 4A, a schematic illustration an exemplary apparatus which may be used for implementing process 300 of FIG. 3, is provided. In FIG. 4A, circuit 400 is shown, which includes memory array 414 comprising a number “n” of bit cells (bit cells not explicitly shown in this view), which are assigned numerical identifiers “1” to “n.” For reading the bit cells, sensing circuits 412_1 and 412_n are representatively shown for bit cells “1” and “n.” The corresponding V_{data} 410_1 and 410_n are compared with selected reference voltages V_{ref} 408_1 and 408_n in sense amplifiers 402_1 and 402_n. NV_latches 404_1 and 404_n store the selected reference voltage information for bit cells “1” and “n” respectively, such that they generate control signals for 2:1 multiplexors or “MUXes” 406_1 and 406_n. The control signals from NV _latches 404_1 and 404_n enable 2:1 MUXes 406_1 and 406_n to select the correct reference voltages V_{ref} 408_1 and 408_n from the first reference voltage V_{ref-} and the second reference voltage V_{ref+}.

With combined reference now to FIGS. 3 and 4A, at Block 302, all NV latches 404_1-404_n for bit cells “1-n” may be initialized to a first control value. This first control value may correspond to a control value to select the first reference voltage V_{ref-} from 2:1 MUXes 406_1-n. In Block 304, all bit cells “1-n,” are written with logical value “0.” In Block 306, all the reference voltages V_{ref} 408_1-408_n will be assigned to or selected as V_{ref-}, and V_{data} 410_1-410_n corresponding to the data values stored in bit cells 1-n will be read using sensing circuits 412_1-412_n and sense amplifiers 402_1-402_n. In Block 308, it will be determined for each bit cell “1-n,” whether the read value at the output of sense amplifiers 402_1-402_n match the expected logical value “0.” For those bit cells that generate the correct read value, their corresponding NV_latches 404_1-404_n are retained at their current state in Block 310, so that they will cause corresponding 2:1 MUXes 406_1-406_n to provide the first reference voltage V_{ref—}. If any one or more of bit cells “1-n” do not generate a correct read value of “0,” then their corresponding NV_latches 404_1-404_n are updated in Block 312, such that they now point to control values for assigning or selecting the second reference voltage V_{ref+} at the output of 2:1 MUXes 406_1-406_n.

In FIG. 4B, reference voltage generator 420 is shown, which can be used to generate the voltages V_{G}_{_{—}}_{load}, the first reference voltage V_{ref1-}, and the second reference voltage V_{ref-} for bit cells “1-n” of circuit 400 discussed with reference to FIG. 4A. The voltage V_{G}_{_{—}}_{load} is used in the sensing circuits of the bit cells, specifically, to gate the load transistor (e.g., a p-channel metal oxide semiconductor (PMOS) transistor used to provide a load for the sensing current passed through the bit cell during read operations. Reference voltage generator 420 is used to provide stable voltages for V_{G}_{_{—}}_{load,} the first reference voltage V_{ref1—}, and the second reference voltage V_{ref-} across bit cells “1-n.”

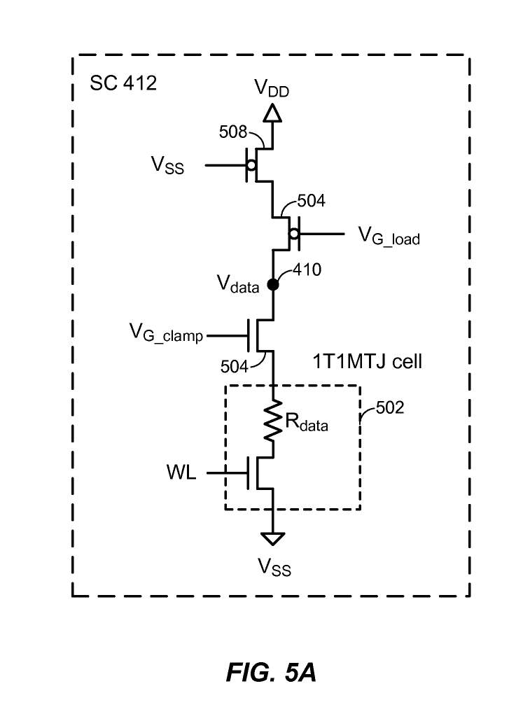

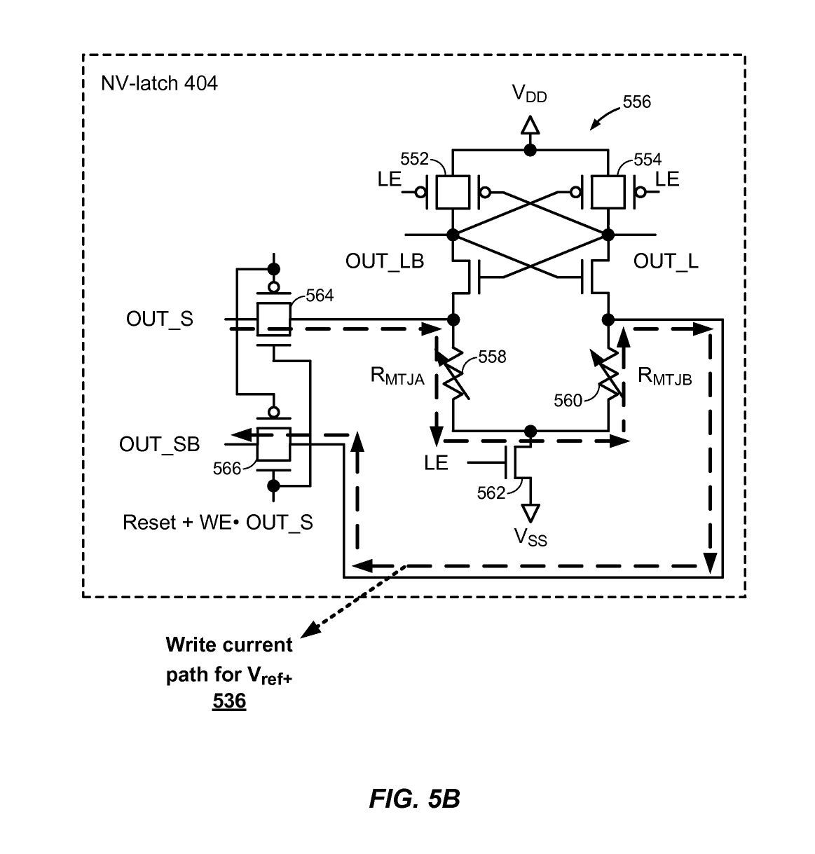

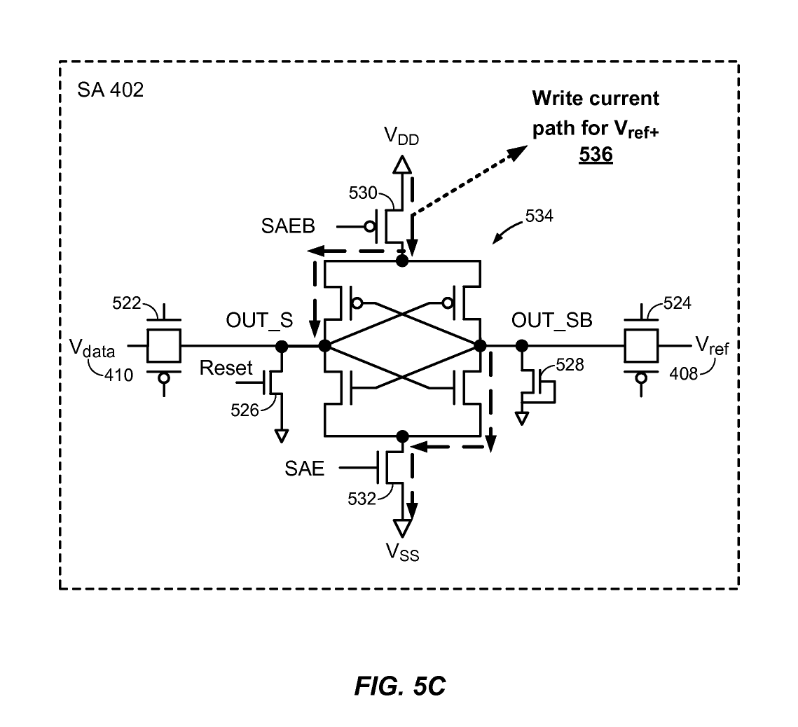

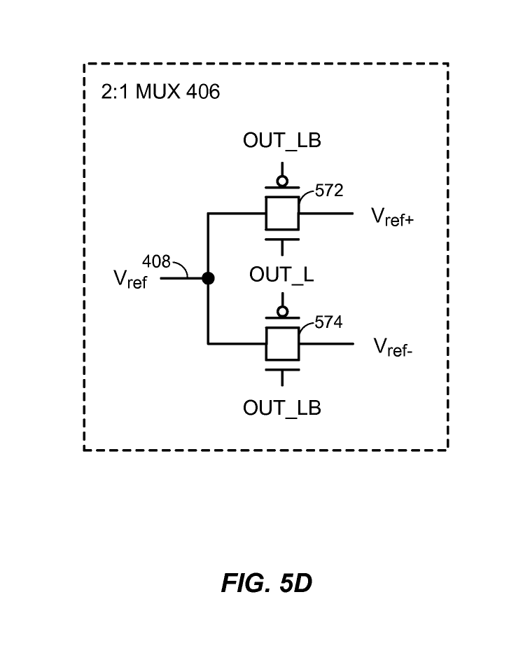

With reference now to FIGS. 5A-D, exemplary circuit schematics and operational details of representative sensing circuit 412, NV-latch 404, sense amplifier 402, and 2:1 MUX 406 which may be initiated in the corresponding blocks shown in circuit 400 of FIG. 4A, are illustrated.

Firstly, FIG. 5A shows an exemplary sensing circuit which includes a single MTJ bit cell 502. Bit cell 502 includes an MTJ element of variable resistance R_{data} and a single access transistor coupled to a word line “WL,” and to ground/negative supply voltage Vₛₛ. The single access transistor is used to enable current to flow through the MTJ element when WL is high, and is thus used to select bit cell 502 for a read/write operation. Due to the single access transistor and the single MTJ element forming bit cell 502, this configuration is referred to as a 1T1MTJ bit cell, as is known in the art. Bit cell 502 is coupled to transistor 504 (which may be an n-channel metal oxide semiconductor (NMOS) transistor, as shown). The gate of transistor 504 is controlled by voltage V_{G}_{_{—}}_{clamp}, which controls the sensing current that flows through bit cell 502. Voltage V_{data} is accordingly developed at node 410 based on the sensing current and the value of R_{data}. As previously described, V_{data} 410 is compared with an appropriate reference voltage V_{ref} 408 in order to determine the value stored in bit cell 502. The voltage V_{G}_{_{—}}_{load} is used to gate load PMOS 504, which is active when V_{G}_{_{—}}_{load} is driven to a sufficiently low value. Another load PMOS 508 is shown, which is connected to negative supply voltage Vₓₓ and is thus always on. Next, the comparison of V_{data} 410 with V_{ref} 408 is discussed with relation to FIG. 5C.

In FIG. 5C, sense amplifier 402 is shown, with a pair of cross-coupled inverters 534 which are used for amplifying the difference between input signals V_{data} 410 and V_{ref} 408. The illustrated configuration for sense amplifier 402 is also referred to as a voltage level sense amplifier (VLSA). When the reset signal is high, NMOS transistor 526 is on, which drives output OUT_S to ground. Transistor 528 is a dummy transistor used to match the output capacitance between OUT_S and OUT_SB, which causes OUT_SB to be driven to positive supply voltage or high voltage level. This combination of OUT_S and OUT_SB is used to program NV_latch 404 to store a control value corresponding to a selection of the first reference voltage V_{ref-} from 2:1 MUX 406, as will be discussed with reference to FIGS. 5B and 5D. The reset signal may be driven high during Block 302 of process 300, illustrated in FIG. 3. When sense amplifier 402 is enabled, the signals SAE and SAEB cause transistors 532 and 530 to be conducting. Pass gates 522 and 524 are also conducting, and the result of comparing V_{data} 410 and V_{ref} 408 is amplified and output on nodes OUT_S and OUT_SB. More specifically, if ΔV=V_{data} 410−V_{ref} 408 is positive, then OUT_S is high, representing a logical value of “1” stored in bit cell 502. Similarly, if ΔV=V_{data} 410−V_{ref} 408 is negative, then OUT_SB is high, representing a logical value of “0” stored in bit cell 502. Thus, if a logical value of “0” is stored in bit cell 502 and the first reference voltage V_{ref-} is used after Reset (e.g., in Block 304), then OUT_SB must be high (e.g., as determined in Block 306, using V_{ref—}). If OUT_SB is not high (e.g., as determined in decision Block 308), then a decision will be made to switch the value of V_{ref} 408 from V_{ref-} to V_{ref+}. Once this switch happens, the write current path for V_{ref+} causes current to flow through transistors 530 and 532 as shown, which drives OUT_S low and OUT_SB high, thus, providing the correct value for bit cell 502 (this corresponds to Block 312 of process 300).

In FIG. 5B, an exemplary circuit schematic of NV_latch 404 is shown as comprising two reference MTJ cells R_{MTJA} 558 and R_{MTJB} 560. The outputs OUT_S and OUT_SB of sense amplifier 402 are used to program reference MTJ cells R_{MTJA} 558 and R_{MTJB} 560. Based on how the reference MTJ cells R_{MTJA} 558 and R_{MTJB} 560, the outputs OUT_L and OUT_LB of the cross-coupled latch 556 of NV_latch 404 provide controls for driving 2:1 MUX 406 of FIG. 5D. Pass gates 564 and 566 are used to selectively transfer the values driven by OUT_S and OUT_SB to program the reference MTJ cells R_{MTJA} 558 and R_{MTJB} 560. In the example of the Reset signal being enabled, OUT_S is low and OUT_SB is high, which writes logic “1” to the reference MTJ cells R_{MTJA} 558 and logic “0” to R_{MTJB} 560. Correspondingly, OUT_LB is high and OUT_L is low, when the control signal LE is on, enabling transistors 552, 554, and 562 to conduct. This drives pass gate 574 of 2:1 MUX 406 of FIG. 5D to be open and pass gate 572 to be closed. Thus, the output V_{ref} 408 of 2:1 MUX 406 is driven with the first reference voltage V_{ref-}. Thus, NV_latch 404 can be written during a reset or initialization phase when the reset signal is high (e.g., Block 302 of FIG. 3).

Following decision Block 308, if any of the bit cells require a second reference voltage V_{ref+} for correct sensing of the values stored therein, then in Block 312, NV_latch 404 is reprogrammed. For this, OUT_SB must be low (as discussed above), which means OUT_S is high. Further, a word enable WE must be on, to indicate that a value was written to the bit cells (e.g., in Block 304). This enables pass gates 564 and 566, and writes a logical “0” in reference MTJ cells R_{MTJA} 558 and logical “1” to R_{MTJB} 560. Correspondingly, OUT_LB is low and OUT_L is high, when the control signal LE is on, enabling transistors 552, 554, and 562 to conduct. This drives pass gate 572 of 2:1 MUX 406 of FIG. 5D to be open and pass gate 574 to be closed. Thus, the output V_{ref} 408 of 2:1 MUX 406 is driven with the second reference voltage V_{ref+}. Thus, NV_latch 404 can be reprogrammed (e.g., Block 312 of FIG. 3).

In this manner, the reference voltage for each bit cell can be particularly configured such that the degradation of sensing margin can be overcome in exemplary aspects. As previously discussed, while the description pertains to selecting from one of two reference voltages, the exemplary aspects can be extended to selection of reference voltages from any number of options to ensure that a bit cell is correctly read for both logical “0” and logical “1” stored therein. Although this is not exhaustively dealt with, if three or more reference voltages are to be selected from, then 2:1 MUX 406 can be correspondingly modified to a 3:1 MUX or a 4:1 MUX, and so on, in order to select from the corresponding number of reference voltages that are available as options, based on particular implementations.

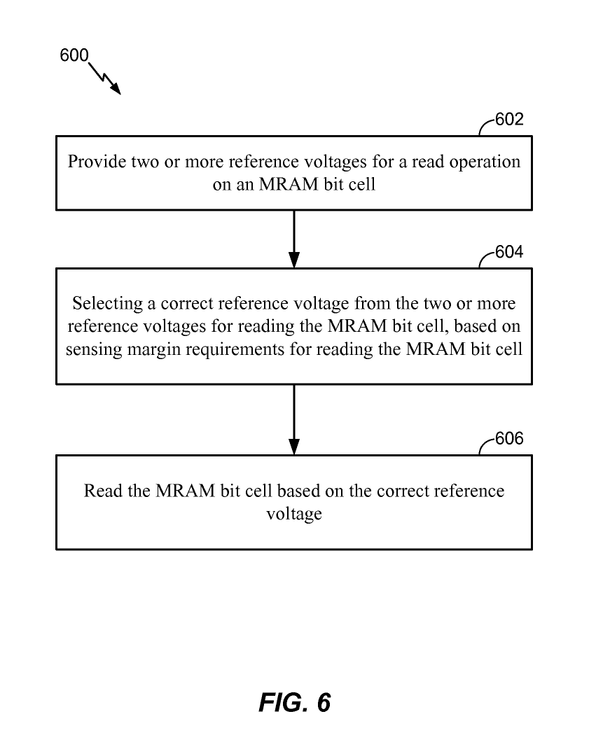

Accordingly, it will be appreciated that aspects include various methods for performing the processes, functions and/or algorithms disclosed herein. For example, as illustrated in FIG. 6, an aspect can include a method (600) of reading a magnetoresistive random access memory (MRAM) bit cell (e.g., bit cell “1” in memory array 414 of FIG. 4), the method comprising: providing two or more reference voltages (e.g., V_{ref+} and V_{ref-}) for the MRAM bit cell-Block 602; selecting (e.g., using 2:1 MUX 406_1 and control from NV_latch 404_1) a correct reference voltage (e.g., V_{ref}) from the two or more reference voltages for reading the MRAM bit cell, based on sensing margin requirements for reading the MRAM bit cell-Block 604; and reading (e.g., using SC 412_1, SA 402_1) the MRAM bit cell based on the correct reference voltage-Block 606.

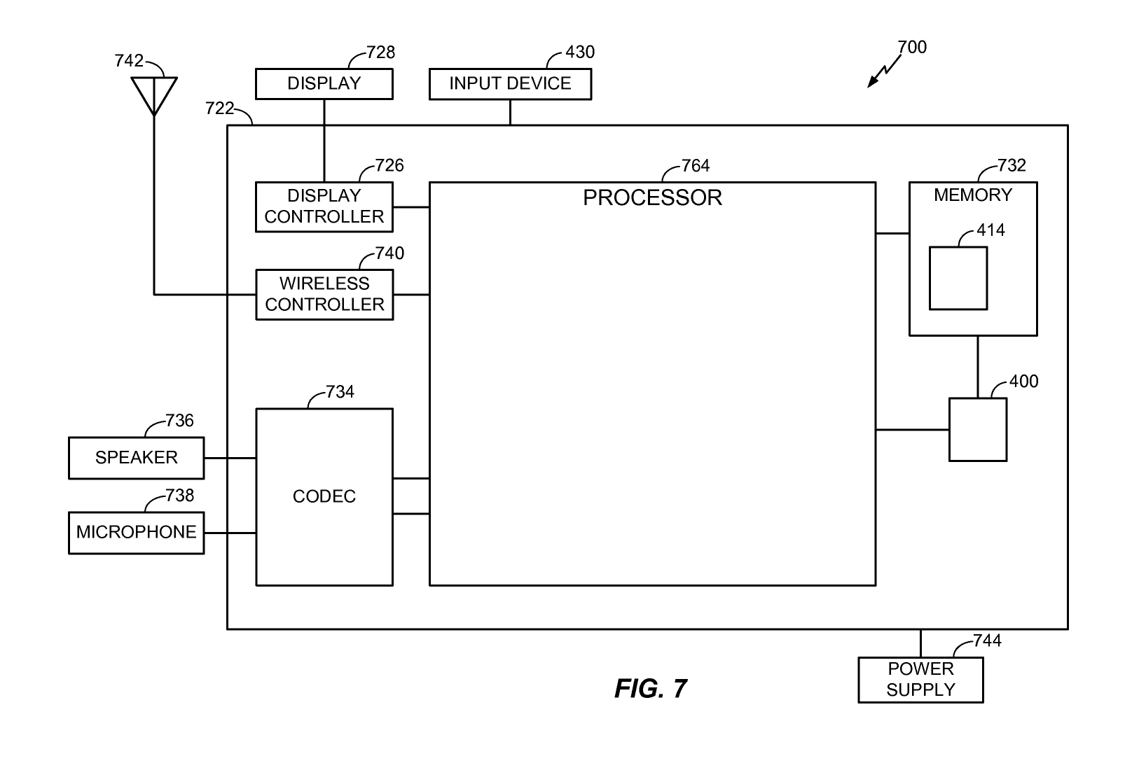

Referring to FIG. 7, a block diagram of a particular illustrative aspect of wireless device 700 configured according to exemplary aspects is depicted. Wireless device 700 includes a processor 764 coupled to memory 732. Memory 732 may comprise memory array 414 of FIG. 4, including MRAM bit cells “1-n,” and associated circuit 400 may be coupled to memory 732 and processor 764. Additionally or alternatively, processor 764 may include another memory structure, such as a cache or a register file (not shown) which comprises similar memory arrays and MRAM bit cells.

FIG. 7 also shows display controller 726 that is coupled to processor 764 and to display 728. Coder/decoder (CODEC) 734 (e.g., an audio and/or voice CODEC) can be coupled to processor 764. Other components, such as wireless controller 740 (which may include a modem) are also illustrated. Speaker 736 and microphone 738 can be coupled to CODEC 734. FIG. 7 also indicates that wireless controller 740 can be coupled to wireless antenna 742. In a particular aspect, processor 764, display controller 726, memory 732, CODEC 734, and wireless controller 740 are included in a system-in-package or system-on-chip device 722.

In a particular aspect, input device 730 and power supply 744 are coupled to the system-on-chip device 722. Moreover, in a particular aspect, as illustrated in FIG. 7, display 728, input device 730, speaker 736, microphone 738, wireless antenna 742, and power supply 744 are external to the system-on-chip device 722. However, each of display 728, input device 730, speaker 736, microphone 738, wireless antenna 742, and power supply 744 can be coupled to a component of the system-on-chip device 722, such as an interface or a controller.

It should be noted that although FIG. 7 depicts a wireless communications device, processor 764 and memory 732 may also be integrated into a set-top box, a music player, a video player, an entertainment unit, a navigation device, a personal digital assistant (PDA), a fixed location data unit, a mobile phone, a smart phone, or a computer.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Accordingly, an embodiment of the invention can include a computer readable media embodying a method of providing a correct reference voltage for reading a magnetoresistive random access memory (MRAM). Accordingly, the invention is not limited to illustrated examples and any means for performing the functionality described herein are included in embodiments of the invention.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A method of reading a magnetoresistive random access memory (MRAM) bit cell, the method comprising:
providing two or more reference voltages for the MRAM bit cell;
selecting a correct reference voltage from the two or more reference voltages for reading the MRAM bit cell, based on sensing margin requirements for reading the MRAM bit cell; and
reading the MRAM bit cell based on the correct reference voltage.

2. The method of claim 1, wherein reading the MRAM bit cell comprises passing a sensing current through the first bit cell to develop a data voltage and comparing the correct reference voltage with the data voltage.

3. The method of claim 2, comprising reading a logical “1” from the MRAM bit cell if the data voltage is greater than the correct reference voltage, and reading a logical “0” if the data voltage is less than the correct reference voltage.

4. The method of claim 1, wherein the correct reference voltage differs from an ideal reference voltage by an offset voltage, wherein the offset voltage is caused by process variations in read circuitry for reading the MRAM bit cell.

5. The method of claim 4, wherein the offset voltage is negative, and selecting the correct reference voltage comprises selecting a first reference voltage of the two or more reference voltages which is less than the ideal reference voltage as the correct reference voltage.

6. The method of claim 4, wherein the offset voltage is positive, and selecting the correct reference voltage comprises selecting a second reference voltage of the two or more reference voltages which is greater than the ideal reference voltage as the correct reference voltage.

7. The method of claim 4, wherein the read circuitry comprises a sensing circuit and a sense amplifier.

8. The method of claim 1, further comprising, prior to reading the MRAM bit cell, determining the correct reference voltage to be one of the two or more reference voltages, storing an indication of the correct reference voltage, and selecting the correct reference voltage based on the stored indication.

9. The method of claim 8, wherein determining the correct reference voltage to be one of the two or more reference voltages comprises writing a first logical value to the MRAM bit cell; reading the first bit cell using a first reference voltage of the two or more reference voltages; and if the read out value matches the first logical value, then treating the first reference voltage as the correct reference voltage.

10. The method of claim 9, further comprising, if the read out value does not match the first logical value, then treating a second reference voltage of the two or more reference voltages as the correct reference voltage.

11. The method of claim 8, comprising storing the indication in a non-volatile latch.

12. The method of claim 8, comprising storing the indication in a one-time programmable (OTP) memory or electrically erasable programmable read only memory (EEPROM) and transferring the indication to a volatile latch during or after power up of the MRAM.

13. The method of claim 8, comprising storing the indication in a second memory cell and transferring the indication to a volatile latch during or after power up of the MRAM.

14. An apparatus comprising:
a magnetoresistive random access memory (MRAM) bit cell;
read circuitry configured to perform a read operation on the MRAM bit cell; and
a multiplexor configured to select a correct reference voltage from two or more reference voltages, based on sensing margin requirements for the read circuitry.

15. The apparatus of claim 14, wherein the read circuitry is configured to pass a sensing current through the MRAM bit cell to develop a data voltage and compare the correct reference voltage with the data voltage.

16. The apparatus of claim 15, wherein the read circuitry is configured to read a logical “1” from the MRAM bit cell if the data voltage is greater than the correct reference voltage, and read a logical “0” if the data voltage is less than the correct reference voltage.

17. The apparatus of claim 14, wherein the correct reference voltage is shifted by an offset voltage relative to an ideal reference voltage, the offset voltage caused by process variations in the read circuitry.

18. The apparatus of claim 17, wherein the offset voltage is negative, and the multiplexor is configured to select a first reference voltage of the two or more reference voltages which is less than the ideal reference voltage as the correct reference voltage.

19. The apparatus of claim 17, wherein the offset voltage is positive, and the multiplexor is configured to select a second reference voltage of the two or more reference voltages which is greater than the ideal reference voltage as the correct reference voltage.

20. The apparatus of claim 14, wherein the read circuitry comprises a sensing circuit and a sense amplifier.

21. The apparatus of claim 14, further comprising logic configured to determine the correct reference voltage from one of the two or more reference voltages, and store an indication of the correct reference voltage, wherein the indication is configured to control the multiplexor.

22. The apparatus of claim 21, wherein the logic configured to determine the correct reference voltage comprises:
logic configured to write a first logical value to the MRAM bit cell;
logic configured to read the first bit cell using a first reference voltage of the two or more reference voltages; and
logic configured assign the first reference voltage as the correct reference voltage if the read out value matches the first logical value.

23. The apparatus of claim 22, further comprising logic configured to assign a second reference voltage of the two or more reference voltages as the correct reference voltage if the read out value does not match the first logical value.

24. The apparatus of claim 22, comprising a non-volatile latch to store the indication of the correct reference voltage.

25. The apparatus of claim 22, comprising a one-time programmable (OTP) memory or electrically erasable programmable read only memory (EEPROM) to store the indication of the correct reference voltage.

26. The apparatus of claim 22, comprising a second memory cell to store the indication of the correct reference voltage.

27. The apparatus of claim 14, integrated in at least one semiconductor device.

28. The apparatus of claim 14, integrated in a device, selected from the group consisting of a set top box, music player, video player, entertainment unit, navigation device, communications device, personal digital assistant (PDA), fixed location data unit, and a computer.

29. A system comprising:
a magnetoresistive random access memory (MRAM) bit cell;
means for providing two or more reference voltages for the MRAM bit cell;
means for selecting a correct reference voltage from the two or more reference voltages for reading the MRAM bit cell, wherein the correct reference voltage meets sensing margin requirements for reading the MRAM bit cell; and
means for reading the MRAM bit cell based on the correct reference voltage.

30. The system of claim 29, further comprising: means for determining the correct reference voltage to be one of the two or more reference voltages, prior to reading the MRAM bit cell; means for storing an indication of the correct reference voltage; and means for selecting the correct reference voltage based on the stored indication.
